(19) United States
(12) Patent Application Publication
(10) Pub. No.: US 2007/0029560 A1
(43) Pub. Date: Feb. 8, 2007

(54) Light-emitting devices with high extraction efficiency

(76) Inventor: Jung-Chieh Su, Hsinchu City (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/260,382

(22) Filed: Oct. 28, 2005

(30) Foreign Application Priority Data
Aug. 4, 2005 (TW) 094126533

(51) Int. Cl. H01L 33/00

(52) U.S. Cl. 257/98

(57) ABSTRACT

The present invention relates to a light-emitting device having a substrate and a light-emitting layer comprising an electroluminescent material, wherein the light-emitting layer (p-n junction) is sandwiched between a p-type cladding layer with a p-electrode layer and an n-type cladding layer with an n-electrode layer. The light-emitting device is characterized in that a light control portion is deposited on a light-exiting surface of the light-emitting device. Said light control portion comprises at least one light-tunneling layer. Said light-tunneling layer has a refractive index with respect to the wavelength of the main emitting-light from the light-emitting layer lower than the refractive indices of the substrate, the cladding layers and the electrode layers. The light extraction efficiency is increased by the light tunneling effect when the emitting-light emitted by the light-emitting layer enters the interface between the epitaxial layer and the surrounding material with an incident angle larger than the critical angle. The tunneling light from the light control portion can be polarized, such that a polarized light-emitting device can be realized in practice.

### BACKGROUND OF THE INVENTION

1. Field of the Invention

The present invention relates to a light-emitting device, such as a light-emitting diode (LED), a resonant cavity LED and a flat-surface type LED (for example, an organic LED (OLED)). In particular, the present invention relates to a semiconductor light-emitting device with a light control portion at least constituted by a light-tunneling layer.

2. Related Art

An electroluminescence (EL) light-emitting device basically comprises a light-emitting portion, which essentially consists of an active layer and cladding layers, with materials capable of operating from near ultraviolet (UV) spectrum to infrared (IR) spectrum. The materials include groups III-V and II-VI semiconductors, semi-conducting polymers and particular binary, ternary and quaternary alloy materials, such as III-Nitride, III-Phosphides and III-Arsenides (for example, GaN, AlGaN, AlInGaN, AlGaInP, GaAlP, GaAsP, GaAs and AlGaAs). A semiconductor laminating portion including a light-emitting layer formed of at least an n-type layer and a p-type layer is formed on a semiconductor substrate, a dielectric substrate, or a glass substrate. When an electric field is applied thereto, holes injected from an anode and electrons injected from a cathode recombine in the light-emitting layer, and photons are generated therein. An exemplary configuration popularly adopted is that the light-emitting layer is sandwiched between the cladding layers. The substrate includes a portion of a laminating buffer layer and a bottom reflective layer. A current diffusing/spreading layer is formed on the surface of the laminating layer, so the current can be injected into the light-emitting layer efficiently. A protection layer is formed on the entire surface of the device. A bonding electrode is partially formed on the surface thereon. This bottom reflective layer provides a high thermal dissipation and a high reflective function, which is designed with a low thermal resistance to allow a high current density operation.

Basically, for a light-emitting device described above, it is recognized that an EL light-emitting device emits photons that are generated from a light-emitting layer and escape from the device into ambient. In considering the difference between the refraction index of the device and that of the ambient medium, there is a relatively small critical angle at the device/surrounding (ambient) medium for total internal reflection, combined with internal light re-absorption within the light-emitting layer result in the external quantum efficiency being substantially less than its internal quantum efficiency, i.e. the so-called critical angle loss. Therefore, the extraction efficiency or external quantum efficiency is defined as the efficiency of light that escapes into the external or the ambient of the device.

Because the refractive indices of the semi-conducting materials from which the device is formed at the emission wavelengths of the device are larger than the refractive indices of the surrounding materials, typically an epoxy or the air in which the device is packaged or encapsulated. The critical angle is given by the following formula:

$${θ}_{c} = {sin}^{- 1} ( \frac{{n}_{2}}{{n}_{1}} ) ,$$

depending on the ratio of the refractive index mismatch. n₁ and n₂ are refractive indices of the incident and the refracted media, respectively. Only the light that has an incident angle smaller than the critical angle will be transmitted through the interface. That is to say, there is an escape cone for light emission with a vertex angle equal to the critical angle as shown in FIG. 1. Assuming that the non-polarized emitted light with isotropic angular distribution and Fresnel reflection loss is included, the ratio of the light transmitted through the interface relative to that which reaches the interface is given by

$$r = ( 1 - \sqrt{1 - {( \frac{{n}_{2}}{{n}_{1}} )}^{2}} ) / 2 = \frac{1 - cos ( {θ}_{c} )}{2} .$$

Thus, losses due to the total internal reflection (“TIR”) increase rapidly with the ratio of the refractive index inside the device to that outside the device. Specifically, for a cubic shaped device, there are six such interfaces or escape cones and the loss should be six times. Therefore, serious deterioration of the total luminescent efficiency occurs.

For example, if GaAs, GaN, sapphire, ITO (InSnO) and glass are typical materials for the topmost surface of the device, their refractive indices are 3.4, 2.4, 1.8, 2.25 and 1.5, respectively, and the external efficiency for escaping to air will be 2.2%, 4.3%, 8.7%, 5.2% and 11%, respectively. Most of the light generated from the light-emitting layer is trapped inside the device. The too-large difference of refractive indices of the interface is the major problem encountered by EL light-emitting devices. Since the light generated by the light-emitting layer is optically characterized as a non-polarized emitted light with isotropic angular distribution light source, photons escape out of the device through all exposed surface. Therefore, a general packaging design concept for an EL light-emitting device is to re-direct the escaping light into a desired output direction and into the escape cone.

Many methods have been taught by prior art techniques to enhance the extraction efficiency and can be divided into four aspects: (I) enhancing the light emission rate; (II) reducing the absorption loss inside the device; (III) increasing the number of escape cones and the cone angle; and (IV) increasing the probability to enter escape cones. Due to the light absorbing property of the contact electrodes, the light-emitting layer or the substrate inside the light-emitting device, the emitting property and the light absorbing property of the device is influenced by its laminating structure.

US Patent Publication No. 20040211969 discloses the usage of a light extraction layer with a structure in which the refractive index decreases gradually toward the exit surface in the thickness-wise direction. As a result, said escape cone angle expands along the transmitting direction of the emitted light and the internal reflection is gradually eliminated. On the other hand, US Patent Publication No. 2005062399 discloses the provision of a light control layer with a structure located between the substrate and the electrodes in which its refractive index gradually increases towards the light emitting layer of the light-emitting device and the substrate has a refractive index lower than that of the light control layer. A spherical wavefront emitted from a point source of the light-emitting layer can be converted into a plan-wave-shaped wavefront, and the total internal reflection is reduced at the interface between the substrate and the ambient medium thereby. Both methods critically depend on the materials used and their complicated manufacturing process of optical multi-layers, and therefore their costs and optical characteristics cannot be controlled effectively in mass production.

However, according to prior art techniques, when the total internal reflection of an incident light happens on the interface between two mediums (wherein the refractive index of the second medium, i.e., the light-tunneling layer, is smaller than that of the first medium, i.e., the laminating layer), part of the incident light will be coupled into a third medium with a refractive index larger than that of the second medium along with the decrease of the thickness of the second medium towards zero if the thickness of the second medium is close to or smaller than the wavelength of the incident light. This phenomenon is the well-known light-tunneling phenomenon. The light-tunneling phenomenon is called frustrated total internal reflection (FTIR), as described in many research papers. The necessary conditions for the optical tunneling phenomenon to occur on an interface between two mediums are as follows: (1) the refractive index of the light-tunneling layer is lower than that of the incident medium; and (2) the thickness of the light-tunneling is much smaller than the wavelength of the incident light. Therefore, except for a light-tunneling layer, a light extraction layer with a refractive index larger than that of the light-tunneling layer can be added between the laminating layer of the light-emitting device and the ambient medium in order to induce FTIR.

Besides, in FTIR, the intensity of the evanescent wave can be increased by the multi-layer laminated structure of dielectric materials as described in “MULTILAYER DIELECTRIC STRUCTURE FOR ENHANCEMENT OF EVANESCENT WAVES” (vol. 35, No. 13, page 2226, 1996, Applied Optics), published by Nesnidal and Walker. Said multi-layer laminated structure of dielectric materials increases the intensity of the evanescent wave by depositing an optical thin film.

Besides, “THE DESIGN OF OPTICAL THIN FILM COATINGS WITH TOTAL AND FRUSTRATED TOTAL INTERNAL REFLECTION” (pages, 24 to 30, Sep. 2003, Optics & Photonics News), published by Li Li, discloses a high extinction ration polarizingbeam splitter with a broadband wide-angle and a high extinction ratio. That is to say, for un-polarized light that has an incident angle larger than the critical angle, its TM polarized light (p polarized light) is reflected and is not transmitted through the total internal reflection interface. Therefore, only the TE polarization light (s polarization light) is transmitted through the total internal reflection interface. Therefore, there is a possibility of manufacturing a polarized light-emitting device. The polarization light (s or p polarization light) of said polarized light-emitting device can be transmitted through said total internal reflection interface only when at least the following conditions are satisfied: (1) when the incident angle is larger than the critical angle (total internal reflection angle); (2) there are a light tunneling layer and a light extraction layer in sequence between the laminated layer and the ambient medium, wherein the refractive index of the light tunneling layer is lower than that of the light extraction layer; and (3) there is another layer with a high refractive index between the laminated layer and the light tunneling layer which has a refractive index higher than that of the light tunneling layer.

### SUMMARY OF THE INVENTION

It is an object of the present invention to convert part of the light captured/trapped by the total internal reflection phenomenon into the transmitted light via the light-tunneling effect, thereby improving the light extraction efficiency of a light-emitting device. In particular, the present invention causes the light with an incident angle larger than the total reflection angle to induce light-tunneling effect by utilizing a light-tunneling layer structure to form a light control portion so as to increase the light extraction efficiency.

The present invention describes a method for use in a light-emitting device, wherein the majority of the emitted light beams enter the interface between the light-emitting device and the ambient medium with incident angles larger than the total internal reflection angle of the light-emitting device. These light beams are internally reflected and go through the internal reflection at least once before escaping from the interface of the light-emitting device and the ambient medium. Besides, in said device, the majority of the light beams are eventually absorbed since the light absorbing property of the contact electrodes and the light-emitting layer is strong. Prior art techniques often improve the light extract efficiency with Bragg reflecting mirrors or surface roughness. In other words, the implementation of improving the extraction efficiency is achieved by increasing the multiple internal reflection mechanism so as to increase the probability for the light to escape. The advantage of this method is cancelled by the relatively increased absorbing light existing in the light-emitting device structure. Therefore, it is important to decrease the multiple internal reflections and to increase the critical angle of escape cones for increasing the extraction efficiency.

The term “escape cone” is used to describe the cones where the light transmitted from the light-emitting layer can escape to the ambient medium. The top point of the escape cone is generated by the total internal reflection. In other words, the top angle is limited by the total internal reflection angle.

The term “light-tunneling layer” to be formed on the light-exiting surface of the light-emitting device is used to induce the frustrated total internal reflection phenomenon. As far as the wavelength of the emitted light of the light-emitting device is concerned, the refractive index of the light-tunneling layer is lower that that of the laminated layer for emitting light wavelength of the light-emitting device.

The term “light extraction layer” of the second part of the light control portion to be formed in the light-emitting device according to the present invention has a refractive index larger than that of the light-tunneling layer of the light-emitting device with respect to the wavelength of the light emitted by the light-emitting device and is formed on the light-tunneling layer of the device. Meanwhile, the “light-extraction layer” is regarded as a light control portion of a light-emitting device and is located on the other side of where the light exits the transparent electrode layers, the laminating layer or the surface of the substrate being far away from the light-emitting layer from said device. The so-called “flat surface light-emitting device” of the present invention is characterized in that it comprises a light control portion, said light control portion comprises a light-tunneling layer that can induce the light-tunneling effect, and a light extraction layer exists on the side of the light-exiting layer facing away the light-emitting layer, wherein the light-tunneling effect of the light beams generated by the light-emitting layer may take place at an incident angle larger than the total internal reflection critical angle. The light control portion comprises at least a light-tunneling layer. Basically, the light control portion can locate between the substrate of the light-emitting device and the ambient medium or between the light-emitting epitaxial layer and the ambient medium. The improvement of the light extraction efficiency is determined by the function of the light-tunneling effect of the light control portion. The major emitted light emitted by the light-emitting device with a light-tunneling layer structure can generate a better polarized light property when the light enters the light control portion with a more oblique incident angle. In practice, a light-emitting device with a polarized light-emitting property can be realized.

An objective of the present invention is to convert a part of the trapped light beams into light beams transmitted through the light-tunneling effect so as to improve the output light of the light-emitting device. Due to the frustrated total internal reflection (FTIR) effect, the incident angle of the light emitted inside the device on the light-exiting surface can become larger than the critical angle. A further method to improve the output light beams of the light-emitting device is to provide at least a light-tunneling layer on one side or the sidewalls of the light-emitting device so as to further increase the light-tunneling effect of the trapped light. Besides, a high reflective coating layer can be added to the sidewalls of the device to ensure that the trapped light cannot leave the device from its sidewalls so as to increase the chances for the light-tunneling effect of the light-exiting surface or the chances for transmitting through the light-exiting surface and contributing to the light extraction efficiency.

Since the laminating structure of the light emitting layer and the optical properties of the ambient medium dictates the angular distribution of the output light from the light-exiting surface, the structure of the light control portion for inducing the frustrated total internal reflection should be designed to make an incident light beam on a surface to be transmitted effectively through a large range of incident angles. That is to say, the light beam output from a light-emitting device with a light-tunneling structure layer should have a larger spatial frequency. Therefore, the light extraction efficiency can be avoided to be reduced due to the total internal reflection of the light beams of the interface between the epitaxial layer or the substrate of the light-emitting device and the ambient medium. Thereby, the improvement of the light extraction efficiency can be achieved.

The present invention relates to a light-emitting device configured to make the light beams generated by the light-emitting device pass the surface of the light control portion of the light-emitting device as a feature. The light control portion comprises two or more dielectric layers. The first part of the light control portion comprises a light-tunneling layer that is formed of a low refractive index material. The light-tunneling layer has a lower refractive index to the wavelength of the emitted light emitted by the light-emitting device than those of the laminating layer, the substrate or the transparent electrode layers. The transparent electrode layers are totally transparent to the wavelength of the major emitted light emitted by the light-emitting device. A second (light extraction) layer with a refractive index larger than that of the light-tunneling layer is formed on top of the first (light-tunneling) layer so as to cause a frustrated total internal reflection (FTIR). In other words, the light-tunneling effect can be manipulated on the interface between the light-exiting surface of the light-emitting device and the ambient medium. As a result, a larger percentage of the emitted light beams can enter the interface between the light-emitting device and the ambient medium with a larger oblique angle, if the interface is flat or not being roughened. These light beams can pass the interface at once and escape by the optical tunneling effect, therefore there exist less possibility for the output light to be re-absorbed inside the light-emitting device. In other words, the effective escape cone angle is larger than the escape cone angle of light-emitting devices without optical tunneling effect. The thickness of the light control portion of the light-emitting device is thin enough to extend the extracted light beams to an emitting angle larger than the total internal reflection angle. In other words, the spatial frequency of the major emitted light generated by the light-emitting layer can be manipulated by the structure of the light control portion.

Besides, the structure of the light control portion is designed to make the major emitted light generated by the light-emitting layer exited from the surface of the light control portion more polarized than a traditional light-emitting device. Besides, this is advantageous for manufacturing a polarized light-emitting device because the major emitted light emitted by the light-emitting layer can be manipulated via the light-tunneling effect to enter the exit surface with an incident angle larger than the critical angle and to escape from the light-emitting device with more polarized light than that of a traditional light-emitting device. Therefore, the light extraction efficiency is substantially improved according to the designed structure of the light-emitting device.

The light-emitting device can be a laser diode, an organic LED (OLED), a polymer LED (PLED), a flat surface LED and a high brightness light-emitting device (HBLED). The materials of the stack of the light control portion can be formed of semiconductor materials or organic/inorganic dielectric materials, such as III-V semiconductor, optical polymer, silica, metal oxide, sol gel, silicon, and germanium.

The process of fabricating a light control portion of the present invention merely utilizes the semiconductor light-emitting device as the embodiment to prevent the confusion to the characteristic of the present invention. But the light-tunneling layer and the light control portion of the present invention can also be applied to other light-emitting devices, such as organic light-emitting devices.

### BRIEF DESCRIPTION OF THE DRAWINGS

FIG. 1 represents a drawing of the simplified path of the light through a single light control portion (i.e., light control portion 10 only comprises a light-tunneling layer 12) of a light-emitting device 1 according to an embodiment of the present invention.

FIG. 2 represents a theoretical simulation result of the reflectivity of the exit interface of the light-emitting device 1 with respect to the thickness of a light-tunneling layer.

FIG. 3a represents a theoretical simulation result of the reflectivity of the exit interface of the light-emitting device 1 with respect to the incident angle, wherein the light-emitting device 1 is a GaN LED (with a refractive index of 2.4) with a SiO₂ light-tunneling layer (with a refractive index of 1.46) with a thickness of 20 nm.

FIG. 3b represents a theoretical simulation result of the reflectivity of the exit interface of the light-emitting device 1 with respect to the incident angle, wherein the light-emitting device 1 is a GaN LED (with a refractive index of 2.4) with a SiO₂ light-tunneling layer (with a refractive index of 1.46) with a thickness of 40 nm.

FIG. 4 represents a drawing of a simplified path of the light through two stacked layers (i.e., a light-tunneling layer 12 and a light extraction layer 11) of a light control portion 10 of a light-emitting device 2 according to another embodiment of the present invention.

FIG. 5 represents a theoretical simulation result of the reflectivity of the exit interface of the light-emitting device 2 with respect to the incident angle.

FIG. 6 represents a cross-section view of the light-emitting device 2 of the present invention.

FIG. 7 represents a cross-section view of a light-emitting device 3 according to another embodiment of the present invention.

FIG. 8 represents a cross-section view of a light-emitting device 4 according to another embodiment of the present invention.

FIG. 9 represents a theoretical simulation result of the reflectivity of the exit interface the light-emitting device 4 with respect to the incident angle, wherein the light-emitting device 4 is a GaN LED (with a refractive index of 2.4) with a high refractive index layer of GaN material (with a refractive index of 2.4), a SiO₂ light-tunneling layer (with a refractive index of 1.46) and a light extraction layer 11 formed of GaN material (with a refractive index of 2.4).

### DETAILED DESCRIPTION OF THE INVENTION

The present invention is described in more detail by referring to the accompanying drawings. The drawings are to describe the preferred embodiments. However, the present invention is exemplified with several embodiments but is not limited by said embodiments. Said embodiments are to disclose the scope of protection of the present invention to persons of ordinary skill in the art in more detail.

According to the present invention, a light-emitting device represents an organic/inorganic electro-luminance light-emitting device with at least one light-emitting layer that can emit light or generate light by applying external power. More specifically, the refractive index is aimed at the peak wavelength of the major emitted light generated by the light-emitting layer. The light-tunneling layer refers to a dielectric layer with a refractive index lower than that of the light-exiting surface layer of the light-emitting device. Said layer is disposed on the light-exiting surface of said light-emitting device and can cause the light-tunneling effect to the emitted light generated by the light-emitting layer and enters the interface between the device and the ambient medium with an incident angle larger than the critical angle.

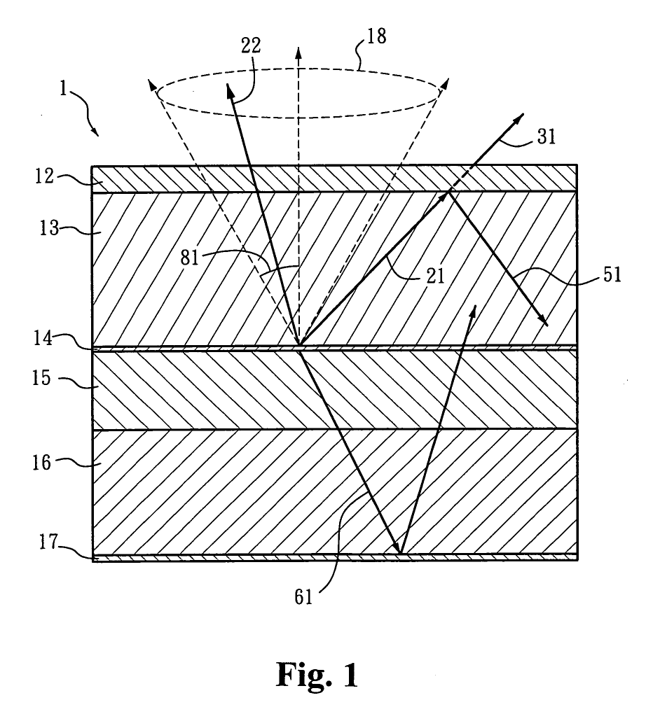

FIG. 1 represents a drawing of the simplified path of the light through a single light control portion (i.e., light control portion 10 only comprises a light-tunneling layer 12) of a light-emitting device 1 according to an embodiment of the present invention. An escape cone 18, a light-emitting layer 14, a p-type cladding layer 13, an n-type cladding layer 15, a substrate 16 and a reflective layer 17 are represented in FIG. 1, respectively, 10 wherein a light control portion 10 merely comprises a light-tunneling layer 12 and p-type and n-type electrodes are not shown in said figure. The incident light beam 22 of the light-tunneling layer 12 can pass through the light control portion 10 easily since its incident angle is smaller than the critical angle 81. However, due to the light-tunneling effect, part of the incident light beam 21 can pass through the cladding layer 13 and the light-tunneling layer 12 (i.e., pass through the interface between the cladding layer 13 and the light-tunneling layer 12) with a refractive index smaller than that of the cladding layer 13 with an incident angle larger than the critical angle 81 and enter into the ambient medium. The necessary conditions for the light-tunneling effect are that the refractive index of the light-tunneling layer 12 is smaller than that of the cladding layer 13 and the thickness of the light-tunneling layer 12 is much smaller than the wavelength of the incident light 21. The light-tunneling effect can cause part of the light (tunneling light 31) to pass through the light-tunneling layer 12 and the other part of the light (light 51) to be reflected. Said tunneling light 31 passes through the light-tunneling layer 12 and is transmitted into the ambient medium. Downward light 61 is reflected by the reflective layer 17 and is transmitted towards the light-exiting surface of the device. Preferably, the light control portion 10 exists on the light-exiting surface and beveled sidewalls, also provided to the sidewalls between the light-exiting surface and the reflective layer 17 (not shown in the drawing). The beveled sidewalls can increase the probability of the main emitted-light generated by the light-emitting layer to be reflected into the escape cone by the sidewalls so as to increase the light-extraction efficiency of the light-exiting surface. Besides, the light control portion 10 is provided on at least one light-exiting surface.

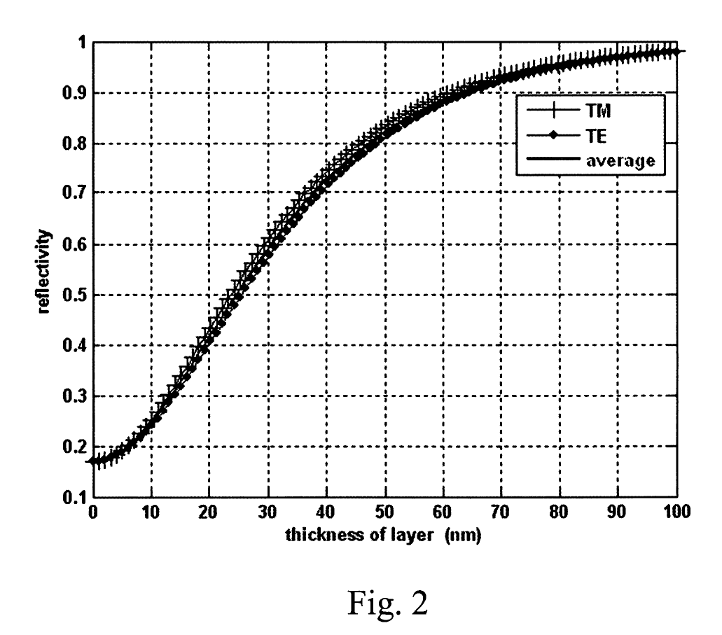

FIG. 2 represents a theoretical simulation result of the reflectivity of exit interface of the light-emitting device 1 with respect to the thickness of the light-tunneling layer of the light-emitting device 1 of FIG. 1. The light-emitting device 1 is a GaN LED (with a refractive index of 2.4) with a silica light-tunneling layer (with a refractive index of 1.46), wherein the wavelength of the major emitted light is 460 nm. The reflectivity will be reduced along with the decrease of the thickness of the light-tunneling layer at an incident angle of 65 degrees which is larger than the critical angle of the GaN/air interface without using the light-tunneling layer.

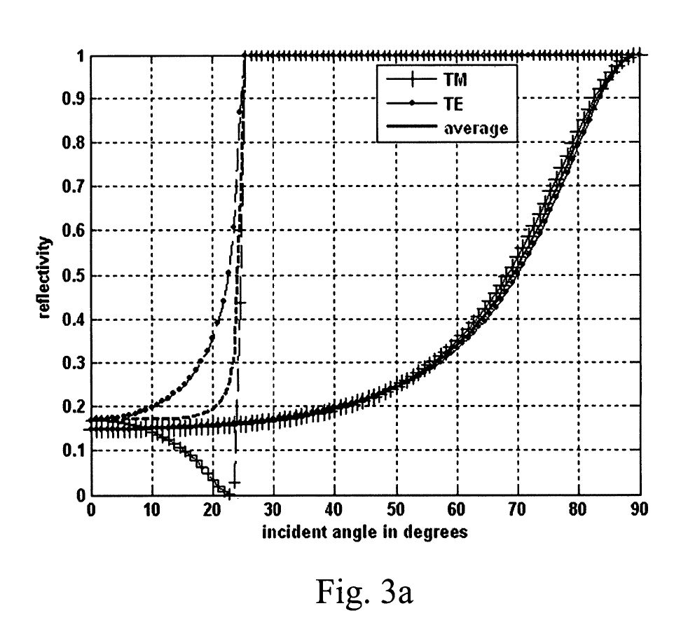

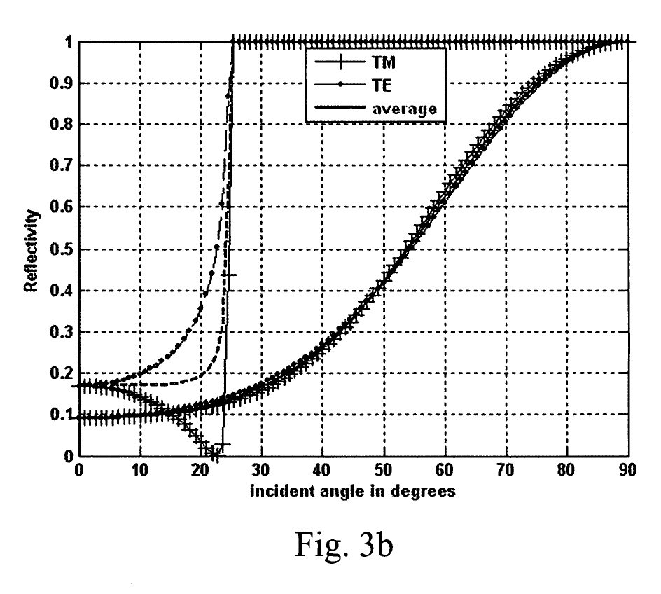

FIG. 3a represents a theoretical simulation result of the reflectivity of exit interface of the light-emitting device 1 with respect to the incident angle, wherein the light-emitting device 1 is a GaN LED (with a refractive index of 2.4) with a SiO₂ light-tunneling layer (with a refractive index of 1.46) with a thickness of 20 nm. The figure indicates that the reflectivity of the interface will be increased rapidly along with the increase of the incident angle when the light-emitting device 1 is without a light-tunneling layer (see the left half, the dashed lines of FIG. 3a). However, the limitation of the critical angle is gradually removed and the extraction efficiency is obviously increased (i.e., the reflectivity is obviously reduced) when the light-emitting device 1 does have a light-tunneling layer see the right half of FIG. 3a).

FIG. 3b represents a theoretical simulation result of the reflectivity of exit interface of the light-emitting device 1 with respect to the incident angle, wherein the light-emitting device 1 is a GaN LED (with a refractive index of 2.4) with a SiO₂ light-tunneling layer (with a refractive index of 1.46) with a thickness of 40 nm. The figure indicates that the reflectivity of the interface will be increased rapidly along with the increase of the incident angle when the light-emitting device 1 is without a light-tunneling layer (see the left half, the dashed lines of FIG. 3b). However, the limitation of the critical angle is gradually removed and the extraction efficiency is obviously increased (i.e., the reflectivity is obviously reduced) when the light-emitting device 1 is with a light-tunneling layer (see the right half of FIG. 3b). However, comparing FIGS. 3a and 3b, it can be realized that the reflectivity is lower for thinner light-tunneling layer at the incident angle larger than the critical angle (for example, larger than 40 degrees). On the contrary, the reflectivity is higher when the light-tunneling layer is thicker.

According to FIGS. 2, 3a and 3b, it is known that the reflectivity of TE wave (p-polarized light) and that of TM wave (s-polarized light) have no obvious difference. In other words, the reflectivity of TE wave (p-polarized light) and that of TM wave (s-polarized light) are very close.

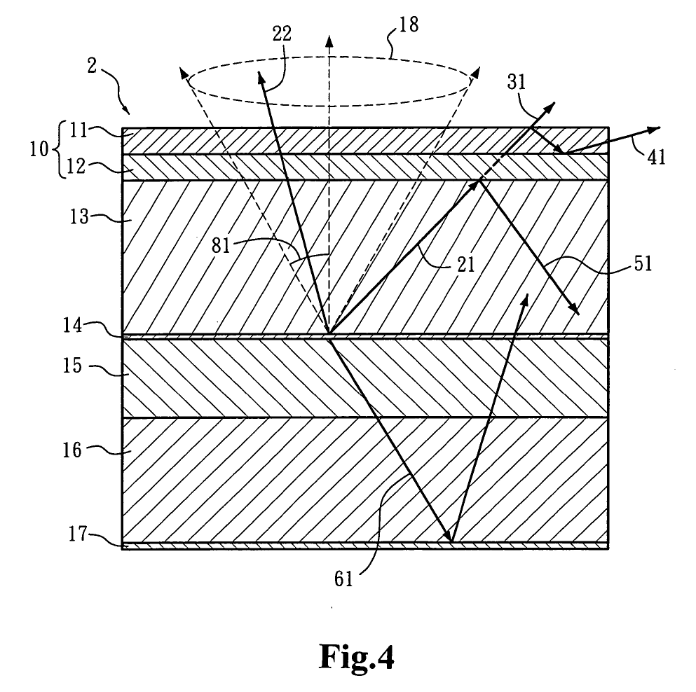

FIG. 4 represents a drawing of a simplified path of the light through a light control portion 10 of a light-emitting device 2 according to another embodiment of the present invention. The light control portion 10 consists of two stack layers (i.e. a light-tunneling layer 12 and a light extraction layer 11). An escape cone 18, a light-emitting layer 14, a p-type cladding layer 13, a n-type cladding layer, 15 a substrate 16 and a reflective layer 17 are consistent with those in FIG. 1. However, the difference between the light-emitting device 2 of FIG. 4 and the light-emitting device of FIG. 1 is that the light control portion further comprises a light-extraction layer 11 formed between the light-tunneling layer and the ambient medium, wherein the refractive index of the light extraction layer 11 is larger than that of the light-tunneling layer 12. The incident light 22 of the light-tunneling layer 12 can pass through easily since its incident angle is smaller than the critical angle 81. However, due to the light-tunneling effect, part of the incident light 21 can pass through the cladding layer 13, transmit through the light-tunneling layer 12 with a refractive index lower than that of the cladding layer 13 (i.e., transmits through the interface between the cladding layer 13 and the light-tunneling layer) and enter into the light-extraction layer with an incident angle larger than the critical angle. The necessary conditions for the light-tunneling effect are: (1) the refractive index of the light-tunneling layer 12 is smaller than that of the cladding layer 13; and (2) the thickness of the light-tunneling layer 12 is much smaller than the wavelength of the incident light 21. The light-tunneling effect will cause part of the light (i.e., the tunneling light) to pass through the light-tunneling layer 12 and to be transmitted into the light extraction layer 11 and another part of the light (light 51) to be reflected. The thickness of the light extraction layer is designed in order to let a large portion of the tunneling light (i.e., tunneling light 31) pass through the light extraction layer 11 and to be transmitted into the ambient medium and only a small portion of the tunneling light 41 is reflected back to the semiconductor layer or the light-extraction layer 11. Besides, due to the difference between the refractive index of the light tunneling layer 12 and that of the light extraction layer 11, the tunneling light 41 will be transmitted or will be multi-reflected in the light extraction layer 11. Eventually, the tunneling light 41 will transmit effectively into the ambient medium. The above phenomenon provides the opportunity of manufacturing a side-emitting light-emitting device for use in flat-panel display applications (for example, LED backlight device light source). Downward light 61 is reflected by a reflective layer 17, and is transmitted towards the light-exiting surface of said device. Only a small part of light 51 will be absorbed in the direction where it cannot tunnel or extract. In said specific LED structure, the best placement of the light-tunneling layer can be varied and manufactured with the limitation of laminating structure of the chip, the materials and manufacturing methods. In practice, the structure and the manufacturing of the light control portion 10 are limited by the chip structure, the complexity and the cost required to fabricate such a structure. These techniques include the epitaxial growth of the light control portion 10. The manufacturing methods of coating or depositing of the light-tunneling layer 12 and the light extraction layer 11 can utilize dipping, spin coating, self-assembly formation and sol-gel deposition process or conventional optical thin film coating, such as sputtering deposition, E-gun deposition and chemical vapor deposition (CVD). Besides, the light extraction layer 11 of the device can use manufacturing methods such as molecular beam epitaxy (MBE), liquid phase epitaxy (LPE), metal-organic chemical vapor deposition (MOCVD), vapor phase epitaxy (VPE) or a combination of these methods. The light control portion 10 and the LED may be formed by a single step or multiple growth steps, with the order of growth determined by the desire chip structure.

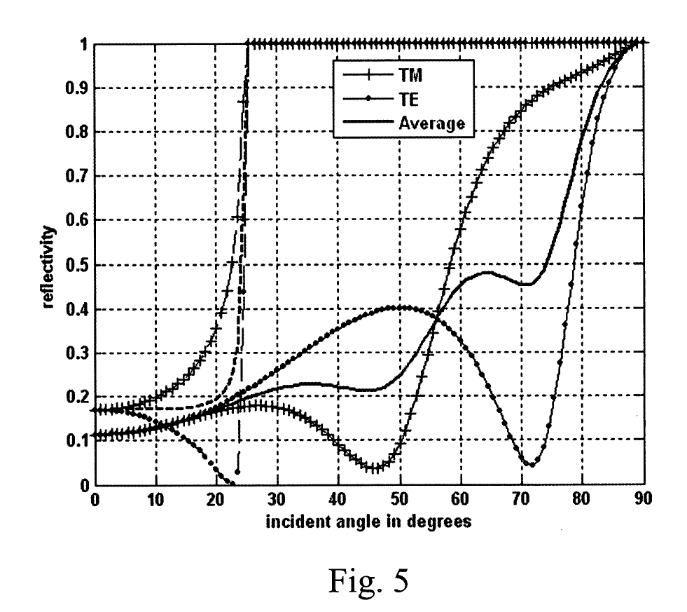

FIG. 5 represents a theoretical simulation result of the reflectivity of exit interface of the light-emitting device 2 of FIG. 4 with respect to the incident angle. The light-emitting device 2 is a GaN LED (with a refractive index of 2.4) comprising an silicon dioxide light-tunneling layer 12 (with a refractive index of 1.46) and a light extraction layer 11 formed of GaN material (with a refractive index of 2.4) disposed on said light-tunneling layer 12, wherein the thicknesses of the light-tunneling layer 12 and the light extraction layer 11 are 20 nm and 100 nm, respectively and the wavelength of the emitting light is assumed to be 460 nm. Regarding the light with an incident angle to the interface between the device and the ambient medium smaller than the critical angle, the reflectivity of the exit interface of the device is lower than that of a device without a light-tunneling layer (please refer to the dashed part of the left half of FIG. 5). The drawing indicates that the average reflectivity of 50% TE polarized light and 50% TM polarized light can be greatly reduced after the critical angle. However, when the incident angle is increased to above 60 degrees, the reflectivity of the exit interface increases rapidly. Besides, the drawing indicates an obvious effect that within a certain range of incident angles (about 30 to 55 degrees), TE polarized light is less reflected than TM polarized light. Therefore, a polarized light-emitting device can be manufactured according to this specified effect. The device can determine whether the major light to be transmitted through the exit surface of the device is TE polarized light or TM polarized light by selecting different ranges of incident angles of the major emitted light of the light-exiting surface.

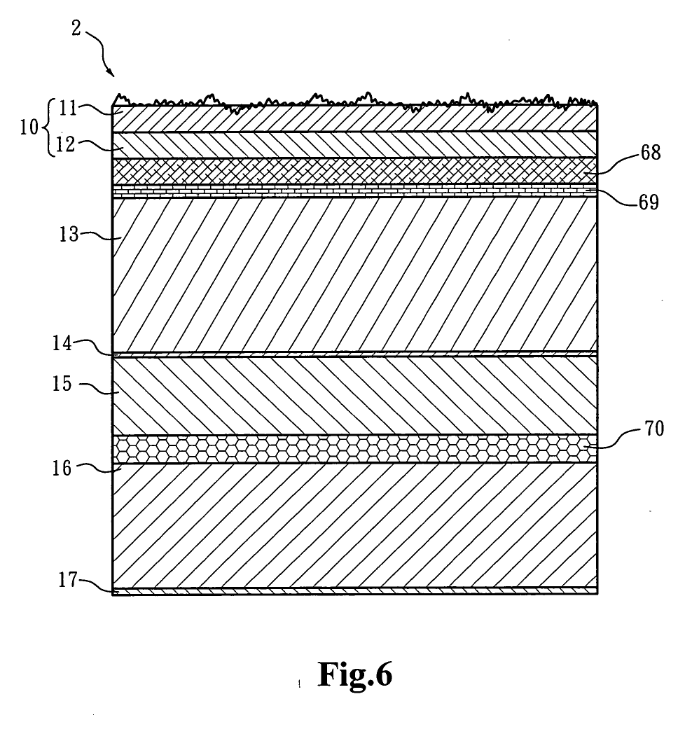

FIG. 6 represents a cross-section view of the light-emitting device 2 (for example, a conventional AlInGaN LED) of another embodiment of the present invention. In this embodiment, the light-emitting device 2 comprises a light control portion 10, said light control portion 10 comprising a light-tunneling layer 12 and a light extraction layer 11 on a transparent electrode ITO layer 68 and a current spreading Au/Ni alloy layer 69. The light-tunneling layer 12 has a refractive index lower than that of the light-exiting layer (i.e., ITO layer 68). The light extraction layer 11 has a refractive index higher than that of the light-tunneling layer 12. The silicon dioxide layer that is generally used for the purpose of protection can be used as the light-tunneling layer 12, as long as it is thin enough to be penetrated by the evanescent wave. In other words, the thickness of the light-tunneling layer is smaller than the wavelength of the major emitted light generated from the light-emitting layer. The light-emitting device 2 further comprises a light-emitting layer 14 (i.e. light-emitting multiple quantum well layer) sandwiched between a p-type cladding layer 13 (i.e., p-type AlInGaN cladding layer) and an n-type cladding layer 15 (i.e., n-type AlInGaN cladding layer). The n-type cladding layer 15 is on top of an epitaxial buffer AlInGaN layer 70 grown on a substrate 16 (i.e., transparent sapphire substrate). A reflective layer 17 (for example, silver or aluminum) is disposed on the other side of the substrate to provide good thermal conductivity and optical reflectivity. The major difference between the light-emitting device 2 and the light-emitting device 2 of FIG. 4 is the surface morphology of the light extraction-layer 11. Specifically, when manufacturing the light control portion 10, the deposition or growing conditions can be manipulated to control the surface morphology of the light extraction layer 11 in order to enhance more light extraction via scattering, diffraction and refraction phenomenon.

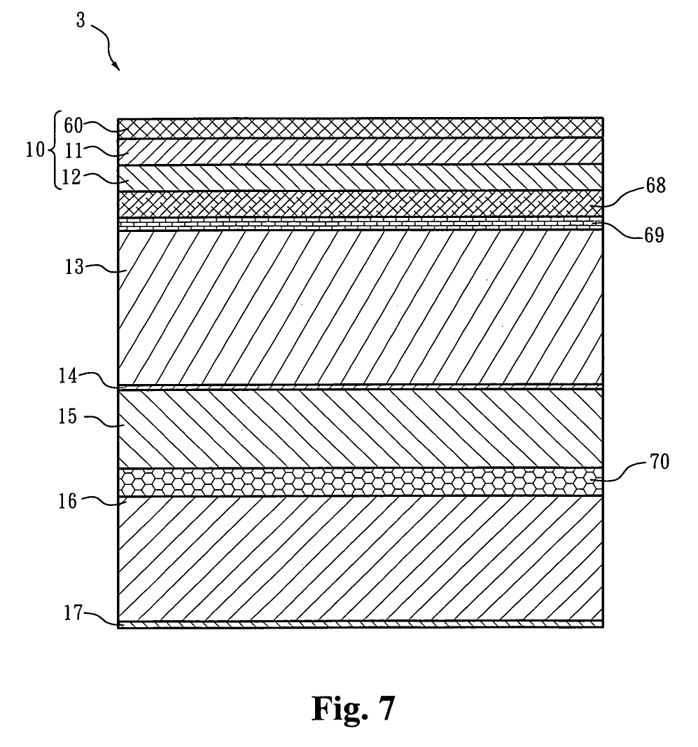

FIG. 7 represents a cross-section view of a light-emitting device 3 according to another embodiment of the present invention. The major difference between the light-emitting device 3 and the light-emitting device 2 of FIG. 4 is that the light control portion 10 further comprises a third layer 60 disposed on the light extraction layer 11 with a refractive index lower than that of the light extraction layer 11 so as to further improve the light extraction efficiency of the light-emitting device 3. The spatial frequency of the transmitted light from the light-emitting layer 14 can be controlled by the light control portion 10 and choice of the materials. The placement of the light-tunneling layer 12 and the distance between the light-tunneling layer 12 the light-emitting layer 14 can also contribute to improve the light extraction efficiency. Therefore, the transmitted light and the tunneling light (from the light-emitting layer 14) impinge the light-exiting surface and transmit into the ambient medium with an incident angle within a range from normal direction to an angle larger than the critical angle.

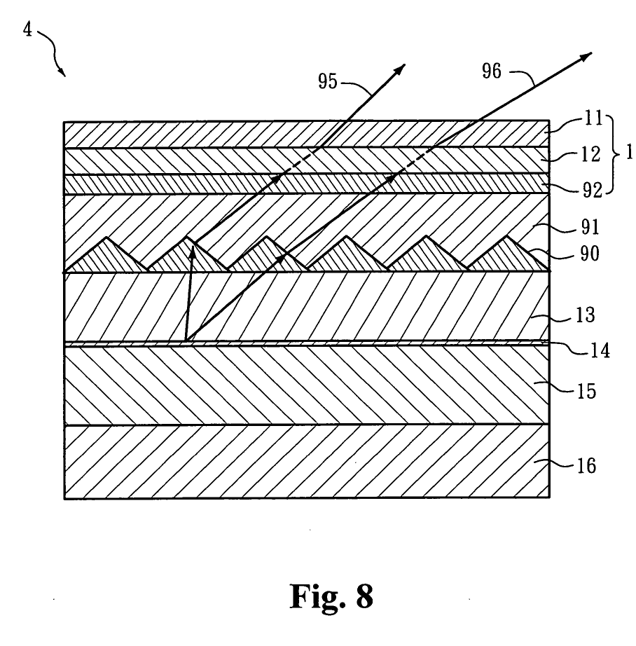

FIG. 8 represents a cross-section view of a light-emitting device 4 according to another embodiment of the present invention. The device is manufactured as a polarized light-emitting device by utilizing the structure disclosed by the article “THE DESIGN OF OPTICAL THIN FILM COATINGS WITH TOTAL AND FRUSTRATED TOTAL INTERNAL REFLECTION” of Li Li, wherein the light control portion 10 can be designed to enhance light extraction efficiency of the first pass to transmit into the ambient medium and to increase the polarization degree of the output light generated from the light-emitting layer 14. In this embodiment, the light-emitting device 4 comprises a light control portion 10 and a light-emitting portion, wherein the light control portion 10 comprises a high refractive index layer 92, a light-tunneling layer 12 and a light extraction layer 11, said light-emitting portion comprising a substrate 16, an n-type cladding 15, a light-emitting layer 14, a p-type cladding layer 13, a light deflection element (LDE) structure 90 and an LDE structure encapsulating layer 91. The purpose for adding a LDE structure 90 is to deflect the light generated from the light-emitting layer enter the light control portion 10 at a more oblique incident angle. The light control portion 10 is located between the light-emitting device and the ambient medium. The LDE structure 90 is a prism array layer, preferably a pyramid array layer. The LDE structure 90 is formed of materials with refractive indices larger than that of the LDE structure encapsulating layer 91. In order to re-direct the major emitted light to impinge the interface between the high refractive index layer 92 and the light-tunneling layer 12 at a larger incident angle, said major emitted light enters the interface between the LDE structure encapsulating layer 91 and the light control portion 10 at a incident angle larger than the critical angle. In other words, the percentage of the emitted light with a more oblique angle with respect to the light-exiting surface increases for a given angular distribution of the emitted light. For example, as shown in FIG. 8, the major emitted light beams 95 and 96 are refracted by an equiangular prism array with an oblique angle preferably between 30 to 70 degrees. If the oblique angle is assumed to be 40 degrees, light beam 95 that enters the LDE structure 90 vertically is refracted by the LDE structure 90 and enters the light control portion 10 with an angle about 40 degrees. Meanwhile, light beam 96 with an incident angle of 40 degrees is not refracted and enters the light control portion 10 with an incident angle of at most 40 degrees. Therefore, light beams 96 and 95 both enter the interface between the LDE structure encapsulating layer 91 and the light control portion 10 at a incident angle larger than the critical angle. In other words, the degree of polarization and the angular distribution of the major emitted light can be manipulated according to the applications of interest.

The LDE structure 90 can be formed in the LED manufacturing process and once the array is formed, the LDE structure encapsulating layer 91 can be grown or disposed to be embedded on the surface of the LDE structure 90 by epitaxial, evaporation, chemical vapor deposition, sputtering, spin coating and dipping techniques. The LDE structure encapsulating layer 91 can be manufactured by materials such as silicon dioxide, silicon nitride, alumina nitride, alumina oxide (for example, SiNx, AlN, SiOx, Si₃N₄, Al₂O₃, SiO₂ or SiN₁₋ₓOₓ), silica aerogel or optical polymers. Preferably, the materials of the LDE structure 90 can be such as III-Nitrides, III-Phosphides and III -Arsenides (for example, GaN, AlGaN, AlInGaN, AlGaInP, GaAlP, GaAsP, GaAs or AlGaAs). The better thickness of disposing materials of the LDE structure 90 is from 100 nm to 10 um. There are two methods to form the LDE structure 90. Firstly, U.S. Patent Publication No. 6,091,085 discloses an embodiment by utilizing GaN to grow on a patterned SiO₂ layer. The method is to create a SiO₂ characteristic structural pattern so as to provide GaN epitaxial growth protrusions on the GaN layer. These characteristic GaN protrusions have an oblique angle, which causes the light to exit the light-exiting surface of the LED with a large oblique angle with respect to the light-exiting surface of the LED. Secondly, U.S. Pat. No. 6,791,117 discloses using a taper RIR or a blade process to form a roughened taper pickup surface. Consequently, the uppermost surface layer has a triangular cross-section. Therefore, the LDE structure 90 can be formed a pyramid-shaped array with inclination preferably between 30 to 40 degrees so as to control the output light from the light-emitting layer 14. The shape of the LDE structure 90 as shown in the FIG. 8 only represents an example of possible shapes and the scope of this invention should not be limited by the shape shown. In addition, the shapes and the dimensions of the LDE structure 90 layer are chosen to optimize the desired light output of the polarized output.

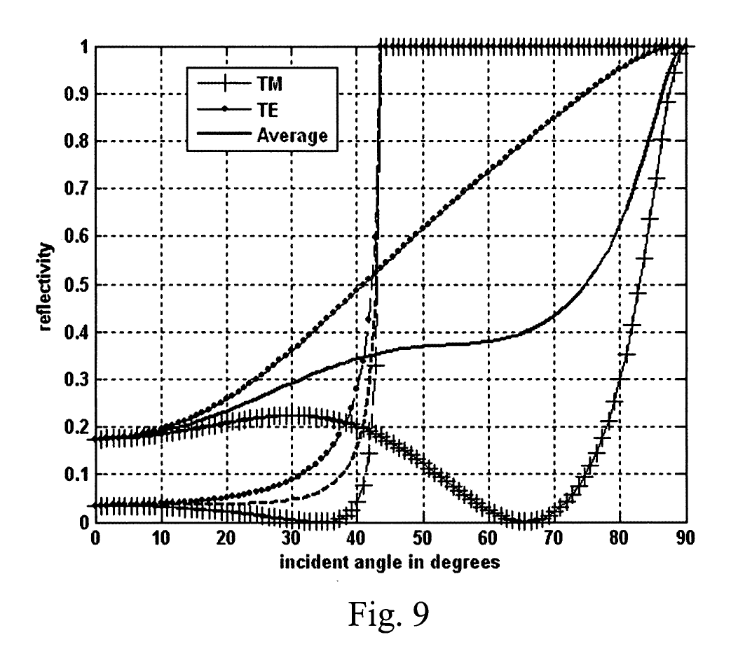

FIG. 9 represents a theoretical simulation result of the reflectivity of exit interface of the light-emitting device 4 of FIG. 8 with respect to the incident angle, the light-emitting device 4 is a GaN LED (with a refractive index of 2.4) with a high refractive index layer 92 of GaN material (with a refractive index of 2.4), a SiO₂ light-tunneling layer 12 (with a refractive index of 1.46), a light extraction layer 11 formed of GaN material (with a refractive index of 2.4) and uses SiO₂ as the material of the encapsulating layer, wherein the thicknesses of the high refractive index layer 92, the light-tunneling layer 12 and the light extraction layer 11 are 40 nm, 40 nm and 100 nm, respectively and the wavelength of the emitted light is assumed to be 460 nm. The drawing indicates that the light control portion 10 functions as a polarizing beam splitter to generate a TM polarized light (p-polarized light) output with an incident angle between 40 to 70 degrees (the reflectivity of the exit interface of the device without the light control portion 10; please refer to the left half, the part represented by dashed lines of FIG. 9). In order to increase the polarizing effect, the LDE structure 90 should have a refractive index larger than that of the material of the LDE structure encapsulating layer 91. The larger difference between the refractive indices of the LDE structure 90 and the LDE structure encapsulating layer 91 can allow the light to enter the surface of the light control portion 10 with a larger incident angle.

The light control portion 10 in contact with the epitaxial layer includes at least a light-tunneling layer 12 with a low refractive index. The light-tunneling layer 12 normally has a refractive index smaller than that of the epitaxial layer material or the substrate material, typically between about 1.35 and 2. When silica aerogel is used the refraction index can be even smaller than the above data and is as low as nearly 1.0. The high refractive index layer materials have indices of refraction larger than 2.0, typically in the range between 2.0 and 3.4. The materials used in the light control portion 10 are selected to create a difference of refractive indices to optimize the transmission of the incident light on the light control portion 10. The light control portion 10 is designed and arranged to provide maximum transmission via the light-tunneling effect of the incident light on the top-most surface and the mesa sidewall of the device. The choice of low or high refractive index materials depends on the materials of the light-exiting surface to enhance the light-tunneling effect. Therefore, for example, for the light-tunneling purpose, the light-tunneling layer 12 has a refractive index smaller than that of the epitaxial semiconductor layer, the transparent electrode, the semiconductor substrate, the glass substrate and the ceramic substrate and can be selected from oxide, nitride, oxy-nitride of silicon, alumina oxide, fluoride of lithium, calcium and magnesium and other alloys containing the above materials or doped with other materials. For the purpose of the frustrated total internal reflection, the high refractive index layer materials are, for example, oxides of titanium, hafnium, tin, antimony, zirconium, tantalum, and manganese, zinc sulfide, III-nitrides, III-Arsenides, III-Phosphides and other alloys materials containing the above materials or doped with other materials.

The light-emitting devices can use the flip-chip packaging technique in all the above embodiments.

According to the above embodiments of the present invention, it is known that: firstly, the light control portion 10 can be used to increase the light extraction efficiency by disposing a light-tunneling layer 12 with a refractive index less than that of the light-exiting surface of the light-emitting device and the thickness of the light-tunneling layer 12 is less than that the wavelength of the major emitted light of the light-emitting device; and secondly, a light extraction layer 11 with a refractive index larger than that of the light-tunneling layer 12 is covered on top of the light-tunneling layer 12. In fact, the effect of the light control portion 10 to the light output of the light-emitting device is to change or increase the angular bandwidth of the exiting light (or spatial frequency), and within the angular bandwidth, the exiting light can transmit energy into the ambient medium. This effect can be regarded as a change or increase of the escape cone angle of the exit interface. In other words, when the light-emitting device is fabricated and the formation of the light control portion is adapted as a part of the light-emitting device, the escape cone angle is larger than the critical angle. The escape cone angle is larger than the critical angle, thereby corresponding to a change of the effective refractive indices of materials at both side of the exit interface whereas, in other words, optical tunneling occurs for light having an incident angle larger than the critical angle. Generally, the properties of the light control portion 10 medium are chosen such that the loss due to absorption of light by the light control portion 10 are considerably smaller than the increase of the light output, due to the provision of the light control portion 10.

Besides, due to the existence of the light control portion 10, the direct transmitting light, with an incident angle less than the critical angle, and the tunneling light, tunnel with an incident angle larger than the critical angle, both contribute to the light extraction efficiency. Besides, the output light beams of the device with the light control portion 10 have shorter light paths than those of the device without the light control portion 10 (with multiple light paths), thus the reflected light is less absorbed. Besides, auxiliary methods (such as surface roughening) can be applied to the present invention to increase light extraction from the light-emitting device as shown in FIG. 6. The difference of refractive indices reflects the incident light on the sidewalls back to the light-exiting surface that can be extracted efficiently from the device. The light-emitting device can also comprise a phosphor/fluorescence material so as to make the major emitted light generated by said light-emitting device and the phosphor/fluorescence material interact with each other and to make the light emitted by the phosphor/fluorescence layer become white light. Although the present invention is a light-emitting device with an enhanced all emitted light capacity, the resolution is not limited to organic LED and light-emitting devices and can also be applied to flat panel display light-emitting sources.

Besides, the light-exiting surface of the present invention is not limited to the top-most surface of the light-emitting device. The purpose for enhancing the light extraction efficiency of the present invention can be achieved as long as the light control portion is disposed on the desired light-exiting surface.

Although the invention has been described with reference to specific embodiments, this description is not meant to be construed in a limiting sense. Various modifications of the disclosed embodiments, as well as alternative embodiments, will be apparent to persons skilled in the art. It is, therefore, intended that the appended claims will cover all modifications that fall within the true scope of the invention.

What is claimed is:

1. A light-emitting device, comprising:
a light-emitting portion, including:
a substrate which is optically transparent;
a light-emitting layer which is sandwiched by a p-type cladding layer and an n-type cladding layer and is optically transparent;
said p-type cladding layer which locates on one side of said light-emitting layer and is optically transparent;
said n-type cladding layer which locates on the other side of said light-emitting layer and is optically transparent;
a p-type electrode layer located on said p-type cladding layer; and
an n-type electrode layer located on said n-type cladding layer,
characterized in that said light-emitting device comprising:
a light control portion, comprising:
a light-tunneling layer which is disposed on a light-exiting surface of said light-emitting device and has a refractive index lower than refractive indices of said substrate, said cladding layers and said electrode layers to the wavelength of the major emitted light emitted by said light-emitting layer and has a thickness smaller than the wavelength of the major emitted light.

2. The light-emitting device of claim 1, wherein said light control portion further comprises a light extraction layer disposed on said light-tunneling layer with a refractive index to the major emitted light larger than that of said light-tunneling layer.

3. The light-emitting device of claim 2, wherein said light-emitting portion further comprises a light deflection element structure and a light deflection element structure encapsulation layer, and said light control portion further comprises a high refractive index layer, said light deflection element structure and said light deflection element structure encapsulation layer disposed on said p-type cladding layer in sequence and the refractive index of said light deflection element structure being larger than that of said light deflection element encapsulation layer, said high refractive index layer disposed under said light-tunneling layer with a refractive index to the major emitted light larger than that of said light-tunneling layer.

4. The light-emitting device of claim 3, wherein said light deflection element structure is a prism array layer or a pyramid array layer.

5. The light-emitting device of claim 3, wherein said light deflection element structure can refract the major emitted light with 30 to 70 degrees.

6. The light-emitting device of claim 3, wherein the material used to constitute said light deflection element structure encapsulation layer is selected from a group consisted of SiNₓ, AIN, SiOₓ, Si₃N ₄, Al₂O₃, SiO₂, SiN₁₋ₓOₓ, silica aerogel and optical polymers.

7. The light-emitting device of claim 3, wherein the material used to constitute said light deflection element structure is selected from a group consisted of GaN, AlGaN, AlInGaN, AlGaInP, GaAlP, GaAsP, GaAs and AlGaAs.

8. The light-emitting device of claim 3, wherein the thickness of said light deflection element structure is 100 nm to 10 um.

9. The light-emitting device of claim 2, wherein said light control portion further comprises a third layer disposed on said light extraction layer with a refractive index to the major emitted light smaller than that of said light extraction layer.

10. The light-emitting device of claim 2, wherein a topmost surface of said light extraction layer is under roughening.

11. The light-emitting device of claim 10, wherein said roughening is proceeded with a depositing process or epitaxial process.

12. The light-emitting device of claim 1, wherein the other side opposite to said light-emitting surface is disposed with a reflection layer.

13. The light-emitting device of claim 1, wherein said light-emitting device is selected from a group consisted of a laser diode device, an organic light-emitting device, a polymer light-emitting device, a flat surface light-emitting device and a high brightness light-emitting device.

14. The light-emitting device of claim 2, wherein said light-emitting device is selected from a group consisted of a laser diode device, an organic light-emitting device, a polymer light-emitting device, a flat surface light-emitting device and a high brightness light-emitting device.

15. The light-emitting device of claim 3, wherein said light-emitting device is selected from a group consisted of a laser diode device, an organic light-emitting device, a polymer light-emitting device, a flat surface light-emitting device and a high brightness light-emitting device.

16. The light-emitting device of claim 13, wherein said light-emitting device is in a flip chip package structure.

17. The light-emitting device of claim 14, wherein said light-emitting device is in a flip chip package structure.

18. The light-emitting device of claim 15, wherein said light-emitting device is in a flip chip package structure.
